(19) United States
(12) Patent Application Publication
(10) Pub. No.: US 2005/0180333 A1
(43) Pub. Date: Aug. 18, 2005

(54) xDSL line tester

(76) Inventor: Michael Kurth, Eningen u. A. (DE)

Correspondence Address: STAAS & HALSEY LLP, SUITE 700, 1201 NEW YORK AVENUE, N.W., WASHINGTON, DC, 20005, US

(21) Appl. No.: 11/085,805

(22) Filed: Mar. 22, 2005

Related U.S. Application Data
(63) Continuation-in-part of application No. 10/673,668, filed on Sep. 30, 2003.

(30) Foreign Application Priority Data
Sep. 2, 2003 (DE) 103 40 423.6

(51) Int. Cl. G01R 31/08

(52) U.S. Cl. 370/248

(57) ABSTRACT

An xDSL, particularly ADSL, line tester has a sine wave generator (2) for generating specified polling frequency signals, particularly “R tones”, which can be put onto the connected ADSL line using an output transformer (4). The response signal from an exchange in the form of a “specified C tone” is filtered in a high pass filter (5) and is integrated in an integrator (7) and is supplied to a central processor unit (1) which prompts a light emitting diode (12) to light up if the detected signal meets the requirements. The central processor unit (1) has stored values for the specified shape and duration of the R tone. The ADSL line tester can thus be used to check connection setup on a purely physical level without the use of software and the like.

### CROSS-REFERENCE TO RELATED APPLICATIONS

This application is a continuation-in-part application of U.S. application Ser. No. 10/673,668, filed Sep. 30, 2003, now pending, priority benefit being claimed thereto and the contents of which are incorporated therein by reference.

This application is based upon and claims the priority of German application no. 103 40 423.6, filed Sep. 2, 2003, and U.S. patent application Ser. No. 10/673,668, filed Sep. 30, 2003, the contents being incorporated herein by reference.

### BACKGROUND OF THE INVENTION

The present invention relates to a line tester for xDSL, particularly ADSL (Asymmetric Digital Subscriber Line), installations for checking connection setup between a PC connected to an xDSL connection socket and the exchange.

The appearance of the World Wide Web (Www) has been accompanied by a continually increasing requirement for high data transfer rates over telephone lines. Complex information supplied on the Internet and new areas of communication, such as Video-on-Demand, Video Conferencing or teleworking, require very high transfer rates and hence new transmission techniques. A normal modem on a normal analogue telephone line can achieve a data transmission rate of no more than 56 kBits per second. An ISDN line allows an already somewhat faster data transfer rate of 64 kBits per second to be achieved. “Channel concentration” makes it possible to double the transmission speed, but requires a higher cost outlay. ISDN, channel concentration and software compression had initially exhausted the options for increasing the data transmission rate.

Since the very start of the 90s, however, there has been a technical solution which allows far higher transfer rates using the conventional telephone network and is called ADSL (Asymmetric Digital Subscriber Line). ADSL is a protocol from the xDSL family. A common feature of all xDSL variants is that they use the conventional copper line network, and the DSL signals thus use the same lines as the conventional telephone signals. In this case, however, DSL uses a different frequency range than the telephone. The analogue telephone signal, which is also abbreviated to POTS (Plain Old Telephone Signal), operates in the range from 0 to 4 kHz, while DSL transmissions use the range from approximately 25 kHz upwards. The particular feature of ADSL technology is that it affords different data transmission speeds in the two directions of transmission, which is the origin of the term “asymmetric”. Toward the user (downstream), it is theoretically possible for up to 8 Mbit/s to flow, and in the opposite direction (upstream) the figure is up to 1 Mbit/s.

Since the two copper wires existing in any conventional telephone line are used, installation generally involves just a second TAE socket for the computer line being installed next to the TAE socket which already exists. The computer is connected to the second TAE socket via a DSL modem. Upstream of the branch to the two TAE sockets, the line contains a “splitter” which separates the DSL signals from the received data stream and forwards them to the modem.

An ADSL line is installed on the analogue telephone line (POTS) on a basis of a standard from the ITU (International Telecommunication Union) which is called ANNEX A. In Germany and in some neighboring countries with widespread ISDN use, the installation can also be effected on the ISDN line, in which case the ANNEX B standard from the ITU is the basis used. ANNEX A and B differ essentially only in the frequency range. The ADSL line is usually installed by a service provider, whose task is to ensure correct operation and the assured features. The Internet access is provided by another company, the ISP—Internet Service Provider. This means that the installer needs to ensure that the ADSL line works, i.e. can set up a connection, after he has set it up. This has entailed a relatively high level of complexity to date, however, namely a PC with a modem and software or just a modem and an ADSL test unit or an ADSL test unit with an inbuilt modem. Another problem in this context is that there are various types of modem, which cannot communicate with every exchange.

A common feature of all known test methods is that it is necessary to use relatively expensive test units on the basis of ADSL testers with protocol software, Ethernet interface etc., and the user also needs to have the appropriate level of training.

A known test unit is a “PING tester”, for example. This also sends a request to a server at the protocol level, and the server then acknowledges this request with the “PING”. For this case too, the full technology including software is required, which means that it is not possible to manufacture simple, inexpensive test units on this basis.

It is accordingly an object of the present invention to specify an xDSL, particularly ADSL, line tester which is of simple design and is easy to implement and to use.

This object is achieved with the features of patent claim 1. Advantageous developments and refinements can be found in the subclaims.

The invention is based on the fundamental consideration that the person setting up the line, and the customer after installation, initially require only information about whether the ADSL line which has been installed can be used to set up a connection to the next exchange (DSLAM, Digital Subscriber Line Access Multiplexer)—regardless of the data rate which can be achieved or other information flowing at a protocol level. A significant aspect for the invention is that, in the course of connections setup by the modem, the first contact is not made at the protocol level.

The first information which the modem sends to the DSLAM comprises the emission of one of a plurality of possible frequency signals, referred to as R tones, which are specified in the aforementioned specifications ANNEX A or B. These frequency signals need to have a particular shape and duration on the basis of said specifications. If the DSLAM now receives these frequency signals and recognizes their shape and duration as being correct, the DSLAM responds to this by emitting a further frequency signal from a plurality of possible frequency signals, namely the “C tones”, as acknowledgement signals.

A fundamental concept of the present invention now involves these specified frequency signals, that is to say R tones in particular, being generated at a purely physical level, and the frequency signals returned by the DSLAM being detected and converted into an OK signal.

The xDSL line driver in accordance with the invention thus contains
means for generating at least one polling frequency signal of prescribed shape and duration which is intended for the connection test,
means for transmitting the frequency signal onto the line,
means for detecting at least one response frequency signal transmitted by a remote station on the line in response to the polling frequency signal, and
means for signaling setup of a connection to the remote station on the basis of detection of the response frequency signal.

In this case, the polling frequency signal is preferably given by at least one R tone based on at least one of the specifications “Annex A”, “Annex B” or “Annex C” published by the ITU (International Telecommunication Union), and the generating means are designed for generating this R tone.

In addition, the detection means are preferably designed for detecting at least one C tone based on at least one of the specifications “Annex A”, “Annex B” or “Annex C”.

The generating means can be provided by a frequency generator such as a sine wave generator actuated or keyed in a suitable manner, so that it sends an R tone of the specified shape and duration to an output transformer. In addition, a power amplifier can be arranged between the frequency generator and the output transformer.

The detection means can have a high pass filter for isolating the response frequency signal and an integrator. These can have a power amplifier arranged between them. Following integration, the signal can be supplied to a Schmitt trigger.

In each one of the ITU specifications ANNEX A, ANNEX B and ANNEX C, R and C tones are defined, wherein the R tones have different frequencies with respect to the specifications and the C tones have different frequencies with respect to the specifications. The R and C tones are always defined in the same way within one of the ITU specifications, however, the frequency ranges are different for ANNEX A, ANNEX B and ANNEX C.

The generating means of the line tester according to the invention are preferably arranged such that they are able to interrogate or poll at least two, preferably all three of these annex versions. Hence, the generating means are able to generate R tones of different frequencies corresponding to the different annex versions and to send the frequency signals to the line.

Accordingly the detection means are arranged such that they are able to detect at least two, preferably all three received C tones having different frequencies according to the different specifications.

The generating means are furthermore preferably arranged such that during the polling—as controlled by the processor—they send the R tones in a timely successive or consecutive manner on the line. Then a corresponding C tone according to the annex version is sent back from the remote station and is detected by the detection means. In this way the line tester according to the invention may detect the given annex version.

The electronic circuit in the ADSL line tester in accordance with the invention preferably comprises a central processor unit (CPU) for controlling the sequences of the R tones to be generated and sent. The CPU is connected by means of an output line to a transmission path containing the frequency generator and is connected by means of an input line to a reception path containing the high pass filter and the integrator. The CPU is preferably freely programmable so that new or other frequencies can be programmed for the R tones to be generated.

The signaling means may comprise at least one light emission diode. Preferably they comprise a number of, for example, three light emission diodes, by which the strength or level of the response signal may be indicated in a gradual manner. For this purpose a level evaluating means for evaluating the level or strength of the response signal may be provided wherein the level evaluating means is connected with the light emission diodes by which the level of the response signal is indicated.

### BRIEF DESCRIPTION OF THE DRAWINGS

FIG. 1 is a block diagram of an electronic circuit for an DSL tester in accordance with an embodiment of the invention.

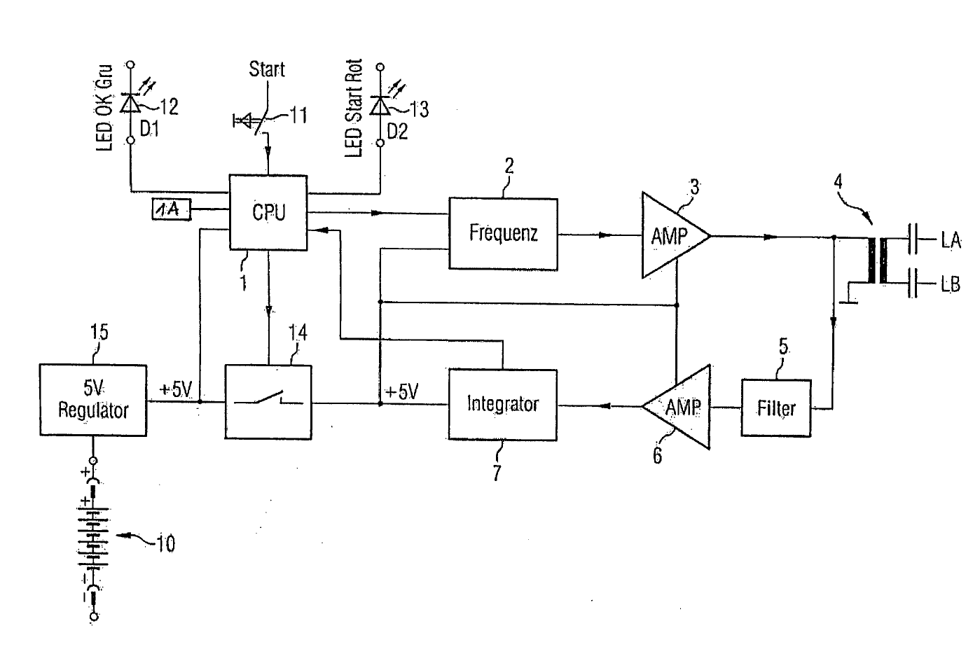

### DETAILED DESCRIPTION OF EMBODIMENTS

A specific exemplary embodiment of the electronic circuit in an ADSL line tester in accordance with the invention is specified below with reference to the single FIGURE of the drawing.

The figure's block diagram of an electronic circuit in an ADSL tester in accordance with the invention can be accommodated in an easily portable housing. The outer wall of the housing contains, inter alia, a pushbutton switch 11 and two light emitting diodes 12 and 13. The housing is connected to an TAE connector which can be plugged into the TAE connection socket for an ADSL line. The voltage supply 10 can be taken from a battery or from a chargeable storage battery.

The pushbutton switch 11 is used by a user to start the test procedure. As a result of the pushbutton switch 11 being operated, the CPU 1 is prompted to send an output signal to the frequency generator 2 on the transmission path. The frequency generator 2 then generates a specified polling frequency signal, particularly a sequence of timely consecutive R tones of different frequencies corresponding to the different annex versions, which is amplified in the power amplifier 3 and is sent to the output transformer 4. The latter transmits the frequency signal to the line which is coupled by means of the TAE connector. Operation of the start signal using the pushbutton switch 11 can be indicated by the red light emitting diode 13.

When a response frequency signal, particularly a C tone, is received, it is routed via the reception path and is isolated from any other signal components by the high pass filter 5. The signal is then amplified in the power amplifier 6 and is supplied to the integrator 7. The output signal from the integrator 7 can also be supplied to a Schmitt trigger (not shown) and can then be detected by the CPU 1. By the level evaluating means, which may be connected with the CPU 1 or contained within the CPU 1, the level or strength value of the response signal is determined and accordingly the CPU 1 prompts output of a signal for actuating the one of the light emitting diodes 12, which corresponds to the level value so that its lighting up indicates to the user the connection to the DSLAM and the quality of the connection.

The CPU 1 contains programmed values for the frequencies and durations of the R tones which are to be emitted consecutively. However, these values can be freely altered by programming or further values may be added thereto by programming.

The voltage supply 10 is connected to a DC voltage regulator 15 which outputs a 5 V DC voltage signal. The CPU 1 is connected to a switch 14 which can supply the 5 V DC voltage signal to the frequency generator 2, to the integrator 7 and to the power amplifiers 3 and 6, for example after the tester has been switched on.

The exemplary embodiment described above relates to an ADSL line tester. The invention can likewise be applied in principle to other line installations from the xDSL family, however.

1. An xDSL line tester, particularly an ADSL line tester, comprising:
means for generating at least one polling frequency signal of prescribed shape and duration which is intended for the connection test;
means for transmitting the frequency signal onto the line;
means for detecting at least one response frequency signal transmitted by a remote station on the line in response to the polling frequency signal, and
means for signaling setup of a connection to the remote station on the basis of detection of the response frequency signal.

2. An xDSL line tester according to claim 1, wherein the means for generating generates at least one R tone based on one of the specifications “Annex A”, “Annex B” or “Annex C” published by the ITU (International Telecommunication Union).

3. An xDSL line tester according to claim 2, wherein the means for generating generates at least two different R tones as they are prescribed in at least two of the specifications “Annex A”, “Annex B” or “Annex C”.

4. An xDSL line tester according to claim 3, wherein the means for generating is designed for the generation of all the different R tones as prescribed in the specifications “Annex A”, “Annex B” and “Annex C”.

5. An xDSL line tester according to claim 3 or 4, wherein the generating means are designed for the timely consecutive generation of the different R tones.

6. An xDSL line tester according to claims 1, 2, 3, or 4, wherein the means for detecting detects at least one C tone based on one of the specifications “Annex A”, “Annex B” or “Annex C” published by the ITU (International Telecommunication Union).

7. An xDSL line tester according to claim 6, wherein the means for detecting detects at least two different C tones as they are prescribed in the specifications “Annex A”, “Annex B” or “Annex C”.

8. An xDSL line tester according to claim 7, wherein the means for detecting detects all of the different C tones as prescribed in the specifications “Annex A”, “Annex B” or “Annex C”.

9. An xDSL line tester according to claim 1, wherein the means for generating comprises a frequency generator, particular a sine wave generator.

10. An xDSL line tester according to claim 1, wherein the means for detecting has a high pass filter and an integrator.

11. An xDSL line tester according to claim 1, wherein the means for signaling comprises at least one light emitting diode.

12. An xDSL line tester according to claim 11, further comprising a level evaluating means for evaluating the level of the response signal, wherein the level evaluating means is connected with a number of, in particular three, light emitting diodes, by which the level of the response signal is indicated.

13. An xDSL line tester according to claim, further comprising a housing having the means for signaling on an outer wall.

14. An xDSL line tester according to claim 13, wherein an outer wall of the housing has a pushbutton switch arranged thereon which a user can use to input a start signal for the test procedure.

15. An xDSL line tester according to claim 1, further comprising a central processor unit connected to the means for generating and to the means for detecting and in which the shape and duration of the at least one polling frequency signal which is to be emitted have been programmed.
